(19) United States
(12) Patent Application Publication
(10) Pub. No.: US 2003/0201549 A1
(43) Pub. Date: Oct. 30, 2003

(54) Pickup apparatus, pickup method and method for manufacturing semiconductor device

(76) Inventor: Tomoyuki Shindo, Nagano-ken (JP)

Correspondence Address: HARNESS, DICKEY & PIERCE, P.L.C., P.O. BOX 828, BLOOMFIELD HILLS, MI, 48303, US

(21) Appl. No.: 10/387,118

(22) Filed: Mar. 12, 2003

(30) Foreign Application Priority Data
Mar. 12, 2002 (JP) 2002-066626

(51) Int. Cl. H01L 23/58

(52) U.S. Cl. 257/798

(57) ABSTRACT

A pickup apparatus in accordance with the present invention pertains to a pickup apparatus that picks up semiconductor chips 1 obtained by dicing a wafer into individual pieces, and is equipped with a chip retaining section 2 with a suction section 3 that sucks and retains a semiconductor chip 1 after dicing, a plurality of minute pores of porous material provided at the suction section 3, and a vacuum pump 4 that evacuates and exhausts gas from the minute pores. By this, occurrences of pickup errors can be suppressed even when semiconductor chips in various sizes and shapes are picked up.

### DETAILED DESCRIPTION OF THE INVENTION

1. Technical Field of the Invention

The present invention relates to a pickup apparatus that picks up semiconductor chips in various sizes and shapes, a pickup method and a method for manufacturing semiconductor devices.

2. Discussion

FIG. 5 schematically shows a perspective view of a structure of a conventional semiconductor chip pickup apparatus. As shown in FIG. 5, the pickup apparatus is equipped with a pushing-up unit 104 that pushes up each single chip, a collet 107, a wafer-ring fixing table 111, a wafer-ring supporting rod 112, a vertical movement unit 113 and an X-Y table 114.

After being adhered to an adhesive tape 102, semiconductor chips 101 are cut and divided into individual pieces by dicing. Also, the adhesive tape 102 is excellent in its expandability, and has a property to lower its adhesive strength by irradiation of ultraviolet rays.

The pushing-up unit 104 is fixed on the vertical movement unit 113, and disposed below the semiconductor chips 101. By this, the pushing-up unit 104 is capable of moving up and down to move closer or away from the semiconductor chips 101 on their lower side. Also, the pushing-up unit 104 is equipped with a function to push up a single semiconductor chip 101 with a plurality of pushing-up needles (not shown) from the lower side of the adhesive tape 102, when the semiconductor chip 101 is picked up.

The collet 107 has a function to apply suction to and attract the semiconductor chip 101 to pick it up, and disposed above the semiconductor chip 101 opposing the pushing-up unit 104. More specifically, the collet 107 applies suction to and attracts the semiconductor chip 101 to pick it up, after the pushing-up unit 104 pushes up the chip from below the adhesive tape 102 to weaken the adhesive strength between the semiconductor chip 101 and the adhesive tape 102.

The wafer-ring fixing table 111 fixes a wafer-ring (not shown) that retains the adhesive tape 102 adhered to the semiconductor chips 101 in a state in which the adhesive tape 102 is extended, and it is fixed to the wafer-ring supporting rod 112.

The wafer-ring supporting rod 112 fixes the wafer-ring fixing table 111 to the X-Y table 114. By moving the X-Y table 114, the wafer-ring fixing table 111 that is fixed to the wafer-ring supporting rod 112 can be freely, horizontally moved in the X-Y directions.

The vertical movement unit 113 freely, vertically moves tips of the plurality of pushing-up needles of the pushing-up unit 104 between a position above the adhesive tape 102 and a position below the adhesive tape, and is capable of individually controlling positions of tips of the plurality of pushing-up needles. For this purpose, the vertical movement unit 113 is equipped with a Z-axis arm 113a, a Z-axis table 113b and a Z-axis motor 113c.

The X-Y table 114 horizontally moves the wafer-ring fixing table 111 in X-Y directions. In other words, the X-Y table 114 is capable of moving any target semiconductor chip 101 to a location immediately above the pushing-up unit 104. For this purpose, the X-Y table 114 is equipped with an X-axis table 114a, an X-axis motor 114b, a Y-axis table 114c and a Y-axis motor 114d.

Next, operations to pick up a semiconductor chip using the pickup apparatus shown in FIG. 5 will be described.

First, the wafer-ring fixing table 111 is moved such that a semiconductor chip 101 to be picked up is located below the collet 107. Then, the collet 107 is lowered to a specified position above the semiconductor chip 101, and the semiconductor chip 101 is vacuum-sucked by the collet 107. At this moment, the pushing-up needles of the pushing-up unit 104 are moved upward to push up the semiconductor chip 101 from below the adhesive tape.

Then, the pushing-up needles are moved downward to peel the semiconductor chip 101 that is vacuum-sucked by the collet 107 from the adhesive tape 102. Then, the semiconductor chip 101 thus peeled off is moved onto a lead frame or a substrate such as a printed circuit board, and mounted thereon, or stored in a chip tray.

In the conventional pick-up apparatus described above, when the size or the shape of semiconductor chips to be picked up is changed, errors may occur in applying suction to and attracting them by the collet. Also, it is difficult to control the pushing amount of the pushing-up needles from below the adhesive tape, and the timing to synchronize their movement with the collet. Timing errors may lead to occurrences of suction and attracting errors by the collet.

The present invention has been made in view of the circumstances described above, and its object is to provide a pick-up apparatus that can restrain occurrences of pick-up errors even when semiconductor chips with different sizes and shapes are to be picked up, a pick-up method, and a method for manufacturing semiconductor devices.

### SUMMARY OF THE INVENTION

To solve the problems described above, a pickup apparatus in accordance with the present invention pertains to a pickup apparatus that picks up semiconductor chips obtained by dicing a wafer into individual pieces, and is characterized in comprising: a chip retaining section with a suction section that sucks and retains a semiconductor chip; a plurality of minute pores of porous material provided at the suction section; and a vacuum pump that evacuates and exhausts gas from the minute pores.

Also, the pickup apparatus in accordance with the present invention may further include a collet that picks up a semiconductor chip that is retained by the chip retaining section by applying suction to and attracting the semiconductor chip.

Also, the pickup apparatus in accordance with the present invention may further include a moving mechanism that moves the collet in all 3 X-Y-Z directions.

Also, in the pickup apparatus in accordance with the present invention, a suction-attracting surface of the collet that applies suction to and attracts a semiconductor chip may have a taper.

Also, in the pickup apparatus in accordance with the present invention, the porous material may preferably be composed of a ceramic material or liquid crystal polymer that is porous and has a large porosity and an excellent mechanical property.

A pickup method in accordance with the present invention pertains to a pickup method for picking up a semiconductor chip which is characterized in comprising:

vacuum-sucking a semiconductor chip to the suction section of the chip retaining section after dicing; and

moving the collet by the moving mechanism over the semiconductor chip, and picking up the semiconductor chip by the collet.

A method for manufacturing a semiconductor device in accordance with the present invention pertains to a method for manufacturing a semiconductor device that is characterized in comprising:

a step of adhering a wafer to an adhesive tape;

a dicing step of cutting the wafer into individual semiconductor chips;

a step of mounting a semiconductor chip that has been cut into an individual piece and adhered to the adhesive tape on the suction section of the chip retaining section;

a step of peeling the adhesive tape from the semiconductor chip through evacuating gas from the minute pores by the vacuum pump to suck the semiconductor chip onto the suction section; and

a step of picking up the semiconductor chip by the collet, after moving the collet by the moving mechanism over the semiconductor chip.

According to the aforementioned method for manufacturing a semiconductor device, after sucking a semiconductor chip after dicing to the suction section of the chip retaining section, the semiconductor chip is vacuum-sucked and attracted by the collet whereby the semiconductor chip is picked up from the suction section. Accordingly, the semiconductor chip does not need to be pushed up from below with pushing-up needles by the pushing-up unit like the conventional technology. For this reason, suction and attraction errors at the time of peeling off semiconductor chips from their fixed places would be eliminated. Therefore, even when the size and the shape of semiconductor chips change, occurrences of suction and attraction errors by the collet can be suppressed, and occurrences of pickup errors can be suppressed.

Also, in the method for manufacturing a semiconductor device in accordance with the present invention, in the step of picking up, the vacuum pump that evacuates gas from the minute pores may preferably be stopped.

Also, the method for manufacturing a semiconductor device in accordance with the present invention may further include a step of die-bonding the semiconductor chip picked up onto a substrate, after the step of picking up.

Also, the method for manufacturing a semiconductor device in accordance with the present invention may further include a step of storing the semiconductor chip picked up in a chip tray, after the step of picking up.

### BRIEF DESCRIPTION OF THE DRAWINGS

FIG. 1(a) schematically shows a perspective view of a chip retaining section that retains a chip after dicing, and FIG. 1(b) schematically shows a perspective view of a state in which a chip is retained by the chip retaining section shown in FIG. 1(a).

FIGS. 2(a)-(c) are cross-sectional views to describe a method for picking up a semiconductor chip in the pickup apparatus in accordance with an embodiment of the present invention.

FIG. 3 shows a plan view of a state in which semiconductor chips are stored in a chip tray.

FIG. 4 shows a structure of a collet in accordance with a modified example of the present embodiment.

FIG. 5 schematically shows a perspective view of a structure of a conventional semiconductor chip pickup apparatus.

### PREFERRED EMBODIMENTS OF THE PRESENT INVENTION

An embodiment of the present invention will be described below with reference to the accompanying drawings.

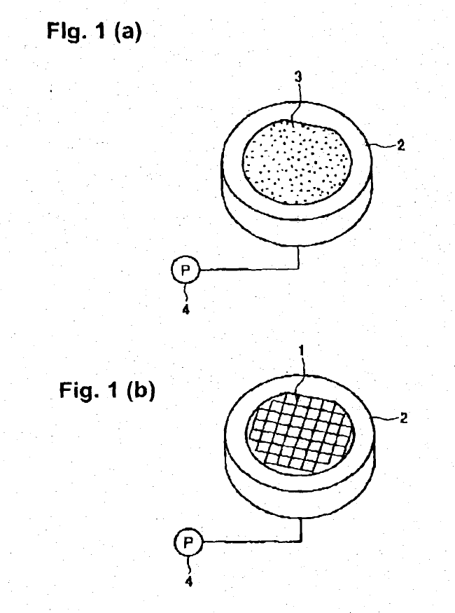

FIG. 1 is a drawing to describe a pickup apparatus in accordance with an embodiment of the present invention.

FIG. 1(a) schematically shows a perspective view of a chip retaining section that retains a chip after dicing, and FIG. 1(b) schematically shows a perspective view of a state in which a chip is retained by the chip retaining section shown in FIG. 1(a).

After a semiconductor wafer is adhered to an adhesive tape (not shown), semiconductor chips 1 are cut and divided into individual pieces by dicing. It is noted that the adhesive tape is excellent in its expandability, and has a property to lower its adhesive strength by irradiation of ultraviolet rays.

The pickup apparatus is equipped with a chip retaining section 2. The chip retaining section 2 includes a suction section 3 that vacuum-sucks the semiconductor chips 1 that have been diced and adhered to an adhesive tape. The suction section 3 includes multiple minute pores in its surface, and its interior is composed of porous material. Any one of various porous materials may be used as the porous material. For example, it can be composed of a ceramic material or a liquid crystal polymer, which is porous or permeable to air with a large porosity and excellent mechanical properties. The size and number of the pores is chosen to permit the operations which are described herein.

The suction section 3 is connected to a vacuum pump 4; and by the vacuum pump 4, the suction section 3 is capable of vacuum-sucking semiconductor chips to its surface. More specifically, after being adhered to an adhesive tape, a wafer is diced into individual semiconductor chips 1; then, ultraviolet rays are irradiated onto the adhesive tape to lower its adhesive strength. Then, the section 3 is placed over the diced wafer and the vacuum pump 4 is activated to create a suction sufficient to hold the array of diced chips against section 3 while an operator peels the adhesive tape from the other side of the chips.

Also, the pickup apparatus may be equipped with a collet (not shown in FIG. 1). The collet is equipped with a function to vacuum-suck, attract and pick up one of the chips 1 from the chip retaining section 2. It is noted that the vacuum pump 4 that is drawing a vacuum from the suction section 3 of the chip retaining section 2 may preferably be stopped at the time of picking up one of the semiconductor chips from the chip retaining section 2.

The collet is mounted on an X-Y-Z table (not shown). The X-Y-Z table horizontally and vertically moves the collet in X, Y and Z directions. In other words, the X-Y-Z table can move the collet to a location immediately above a specified semiconductor chip to be picked up, and also can move it vertically. For this reason, the X-Y-Z table is equipped with an X-axis table, an X-axis motor, a Y-axis table, a Y-axis motor, a Z-axis table, and a Z-axis motor.

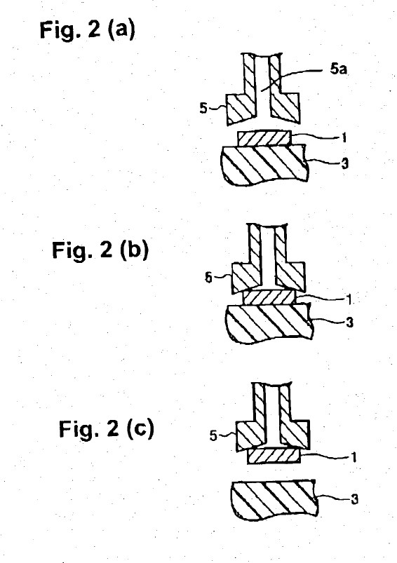

Next, operations to pick up a semiconductor chip by using the pickup apparatus are described with reference to FIGS. 2(a)-(c).

FIGS. 2(a)-(c) are cross-sectional views to describe a method for picking up a semiconductor chip in the pickup apparatus in accordance with an embodiment of the present invention.

First, as shown in FIG. 2(a), the collet 5 is moved to a location above a semiconductor chip 1 at the suction section 3, and then is lowered to a specified position above the semiconductor chip 1. The collet 5 has a vacuum suction aperture 5a, and the vacuum suction aperture 5a connects to a suction-attracting surface of the collet. The suction-attracting surface is a section that sucks and attracts the semiconductor chip 1, and has a radially outwardly diverging taper thereby presenting a cone-shaped chip engaging surface. As a result, when the collet 5 vacuum-sucks and attracts the semiconductor chip 1, the chip engaging surface of the collet comes in contact with an upper outer circumference of the chip. Accordingly, damage to the chip is minimize since only the outer edges of the chip are contacted by the collet 5 in this embodiment.

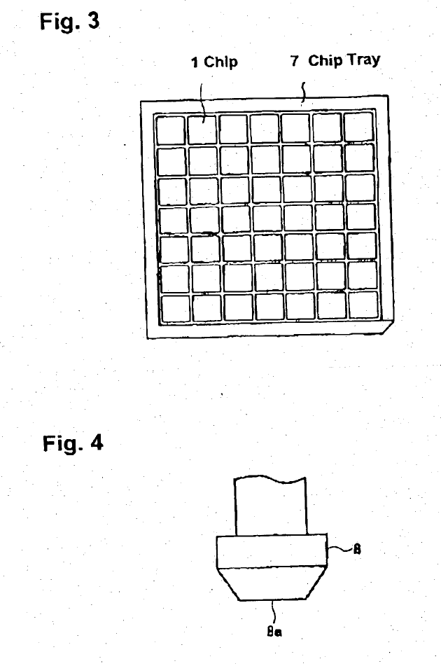

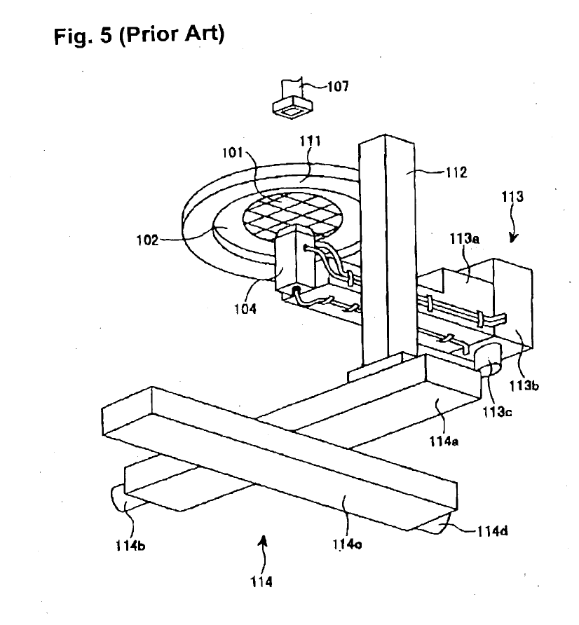

Then, as shown in FIG. 2(b), the collet 5 is lowered to the semiconductor chip 1, and the semiconductor chip 1 is vacuum-sucked and attracted by the collet 5. Then, as shown in FIG. 2(c), the collet 5 is moved upward to remove the semiconductor chip 1 from the suction section 3. Then, the semiconductor chip 1 is transferred onto a lead frame or a substrate such as a printed circuit board, may be flipped and bonded, or may be stored in a chip tray 7 as indicated in FIG. 3.

In accordance with the present embodiment described above, after being adhered to an adhesive tape, a wafer is diced into individual semiconductor chips 1; then, the semiconductor chips 1 adhered to the adhesive tape are transferred to the suction section 3 of the chip retaining section 2; and the adhesive tape is peeled away while the semiconductor chips remain attached to the suction section 3 by drawing a vacuum by the vacuum pump 4. In this manner, the array of semiconductor chips 1 after having been diced are simultaneously sucked to the suction section 3. Then, an individual semiconductor chip 1 is vacuum-sucked and attracted to the collet 5, and then the semiconductor chip 1 is removed from the suction section 3. Accordingly, the semiconductor chip does not need to be pushed up from below with pushing-up needles by the pushing-up unit like the conventional technology. For this reason, suction and attraction errors at the time of peeling off semiconductor chips from their fixed places would be eliminated, and the picking action is quicker. As a result, the yield of the pickup apparatus is improved, and the operating efficiency of the apparatus can be improved. As a consequence, even when the size and the shape of semiconductor chips change, occurrences of errors in suction and attraction by the collet 5 can be suppressed, and occurrences of pickup errors can be suppressed.

Also, in the present embodiment, an improvement in handling of semiconductor chips, as they become thinner (for example, when the thickness of semiconductor chips becomes to be 50 μm-100 μm), can be expected.

FIG. 4 shows a structure of a collet in accordance with a modified example of the embodiment described above. In this modified example, descriptions of the same portions as those of the above embodiment are omitted, and only different portions will be described.

In the embodiment described above, the collet 5 shown in FIG. 2 is used. However, the modified example uses a collet 8 in which its chip engaging surface 8a is flat as shown in FIG. 4. Effects similar to those of the aforementioned embodiment can also be obtained by this modified example.

It is noted that the present invention is not limited to the embodiment described above, and many modifications can be made and implemented.

As described above, the present invention can provide a pickup apparatus, a pickup method and a method for manufacturing a semiconductor device, which can suppress occurrences of pickup errors even when semiconductor chips in various sizes and shapes are picked up.

The disclosure of Japanese patent application No. 2002-06626 filed Mar. 12, 2002 is hereby incorporated by reference.

What is claimed is:

1. A pickup apparatus for transferring semiconductor chips that have been diced, said apparatus comprising:
a chip retaining section having a suction section for engaging the semiconductor chips, said suction section being made from porous material; and
a vacuum pump connected to the suction section for drawing a vacuum through the porous material sufficient to hold the chips against the suction section.

2. A pickup apparatus according to claim 1, further comprising a collet that picks up an individual semiconductor chip that is retained by the chip retaining section by applying suction to and attracting the semiconductor chip.

3. A pickup apparatus according to claim 2, further comprising a moving mechanism that moves the collet in X, Y and Z directions.

4. A pickup apparatus according to claim 3, wherein the collet has a tapered chip engaging surface for contacting outer edges of the chip.

5. A pickup apparatus according to claim 1, wherein the porous material is composed of a ceramic material or liquid crystal polymer.

6. A pickup method for picking up semiconductor chips, said method comprising:
dicing a semiconductor wafer into an array of chips;
transferring the chips to a retaining device by drawing a vacuum through a porous surface in the device; and
moving a collet over one of the chips, and picking up the semiconductor chip by the collet.

7. A method for manufacturing a semiconductor device comprising:
adhering a wafer to an adhesive tape;
dicing the wafer into individual semiconductor chips;
engaging the chips with a chip retaining device;
drawing a vacuum through a porous section of the retaining device;
peeling away the adhesive tape from one side of the chips while the other side of the chips are held against the retaining device by the vacuum;
moving a collect over one of the chips; and
picking up the semiconductor chip with the collet.

8. A method for manufacturing a semiconductor device according to claim 7, wherein the vacuum is stopped while the collet picks up the chip.

9. A method for manufacturing a semiconductor device according to claim 8, further comprising the step of die-bonding the semiconductor chip picked up onto a substrate.

10. A method for manufacturing a semiconductor device according to claim 8, further comprising the step of storing the semiconductor chip picked up in a chip tray.
